(19) United States
(12) Patent Application Publication
(10) Pub. No.: US 2016/0312952 A1
(43) Pub. Date: Oct. 27, 2016

(54) MAGNETIC PIVOT APPARATUS FOR VERTICAL MOUNTING

(71) Applicants: Robert William Kalis, Mesa, AZ (US); Amy G. Kalis, Mesa, AZ (US)

(72) Inventors: Robert William Kalis, Mesa, AZ (US); Amy G. Kalis, Mesa, AZ (US)

(21) Appl. No.: 15/152,554

(22) Filed: May 12, 2016

Related U.S. Application Data
(63) Continuation-in-part of application No. 13/971,853, filed on Aug. 21, 2013, now abandoned.

(51) Int. Cl. F16M 13/02; E05D 7/00; A47B 97/00; G09F 15/00; E05D 3/10; F16B 1/00; H05K 7/16; H01F 7/02; F16C 11/06

(52) U.S. Cl. CPC F16M 13/022; H01F 7/0252; E05D 7/009; A47B 97/001; F16C 11/06; E05D 3/10; F16B 1/00; H05K 7/16; G09F 15/00; F16B 2001/0035

(57) ABSTRACT

A Magnetic Pivot Apparatus For Vertical Mounting with a unique elongated mounting surface that is ideal for mounting on the outer corners of most buildings and housing that use metallic corner bead edging that is typically 1.5″ and 2.5″ in width. In addition, the invention disclosed can be used on more traditional surface such as the front or side of a refrigerator or any other surface that have ferromagnetic and paramagnetic properties.

This application is a Continuation In Part (CIP) of Ser. No. 13/971,853, filed Aug. 21, 2013 by the present inventors, which is incorporated by reference.

### BACKGROUND—PRIOR ART

Message and clip boards have many variations and means for connecting to a surface. In particular, a message center in the kitchen will often involve a refrigerator for displaying messages. A typical set up usually involve mounting the message board to the front surfaces of the doors using magnets, suction cups or tape to hold the message board to the surface. More extravagant message boards may included a white erasable pen surface used to write messages on and additional compartments for holding supplies. Side mounting to a refrigerator is possible with these same devices but the main viewing surface is typical parallel with the mounting surface. This fixed side mounting makes the visible front hard to see. All prior message board systems tend to have a main rectangular base from which to attach the many variations such as doors, containers, holders to name a few.

U.S. Pat Nos. 7,431,251 and 7,374,142 to Caenvali (2008) shows magnetic mounting base plates along with a magnetic object holder which is not include part of the present invention. U.S. Pat. No. 6,425,560 to Dembowiak (2002) show a magnetic hook design used to hold a calculator or to hang object from using a hook variation. This idea lacks consideration for a wall mount that would require an elongated mounting surface to provide adequate surface area to hold an object to a vertical surface. U.S. Pat. No. 6,425,560 to Diatzikis (2015) shows a magnetic mount specific to a smooth surface such as glass. This invention relies on an additional suction cup and is not intended for a metal surface. U.S. Pat. No. 7,934,330 to Nicolaisen (2006) show a magnetic device used on wall but includes an additional metal plate that must be mounted first to attach the object to the wall. The idea addresses the problem of getting a picture adjusted to the correct height. This idea relies on the plate being secure to the wall to hold the weight of the object. The patent idea submitted illuminates this step. Patent 2007/0290588 to Oh (2007) describes a hinged display attached to the front of a refrigerator. The invention describes an indented section formed into the refrigerator door to allow the display to lay flat when pushed into the door. This patent would involve a more permanent attachment to the wall. Patent 2006/0225331 to Evans (2006) shows a magnetic display system comprising of a primary fixed panel and secondary panels attached with hinges. The secondary panels have a 1^{st} and second surface for message displays. This invention adds extra weight with the primary panel and relies on the magnets being placed throughout the primary panel surface. Since the primary surface is relied on for the secondary surfaces, this invention teaches away from using the hinge as the primary device used to secure only a primary display to a surface. U.S. Pat. No. 7,040,899 to Armstrong (2006) shows another free standing message board. This invention shows a primary surface with hinged panels for message display. Its primary use is for moving and displaying messages not in a fixed position as indicated by the carrying handle on the top of the invention. U.S. Pat. No. 5,948,498 to Bianco (1999) shows a magnetic wall mount message board that features multiple sections for various message types. Though this invention combines many previous designs into one, it is still only a message board. This invention does not incorporate a hinge. U.S. Pat. No. 5,947,825 to Rosen (1998) shows a refrigerator mount message center with one or more hinged panels.

The invention allows the expansion of the message center using the hinged panels. The messages displayed are only shown on the front surfaces of the base panel as well as the front surface of the hinged modules in the open position

The invention is used to hide the messages when all the panels are closed. U.S. Pat. No. 5,528,796 to Perry (1996) shows a hinged display that allows the message to be placed flat on a desktop. This patent teaches away from any wall mountings and is intended for desktop computing/data entry aid. U.S. Pat. No. 5,430,965 to Lai (1995) shows a message board apparatus for stabilizing a message in a automobiles using suction cups. The device is also shown on a refrigerator but the message is always parallel with the surface it is mounted to. The invention also includes lighting presumably to see the message in low lighting. There is no hinge to the design. U.S. Pat. No. 5,161,321 to Kuhnke (1992) uses a primary base for the display for storage and the display as a cover to the storage. The hinge is integral to the base and display with the base used to support the display. This invention relies on the base panel to support the main display and not the hinge itself. U.S. Pat. No. 5,131,849 to Perrero (1991) uses a primary base for a display and secondary displays as a cover to the base display. The hinge is integral to the base and display with the base used to support the display. This invention relies on the base display to support the main display and not the hinge itself. U.S. Pat. No. 4,828,502 to Leahy (1989) has a primary base display with a hinged cover panel to cover the message when not in use. The panel can serve as a picture of dry erase display but relies on the base panel wall mounts for support. The base wall mount is required. The current invention replaces this base panel with only the hinge to mount the display. U.S. Pat. No. 7,347,020 to Ray (2008) shows a message board with a hinge that is nothing more than a box mounted on the wall. The utility of this design is to allow the message board to also hold messaging supplies or other items. The message board doubles as a frame for art work when the compartments are closed. U.S. Pat. No. 4,738,043 to Ernst (1988) is another frame type display using a hinge to swing the cover away in order to change the message behind the frame. The door that swings is see through and is nothing more than a frame for the underlying message. U.S. Pat. No. 4,869,452 to Bennett (1989) has a unique hinge mechanism primarily used to flip paper and provide a dual surface for ordinary pads. The device is intended to be placed on a table top. U.S. Pat. No. 4,545,768 to Hinnen (1985) a base with multiple compartments as well a secondary hinged panels that also have compartments. These panels rely on the base panel for the wall mount support. Since the base and panels contain compartments, this presumes more mass and a greater mounting force to support the entire invention. The panels rely on the base compartment for support and not just a hinge directly mounted to the wall. U.S. Pat. No. 4,466,639 to Fennegan (1984) shows a hinged clip board with a magnetic insert for easy removal of a note pad. The invention teaches away from any wall mounting for use. U.S. Pat. No. 7,469,869 to Killion (2008) is a device interface to allow a magnetic connection to a non magnetic surface. This device could be used on refrigerators but is only part of a message display system. It does not contain a hinge mechanism which would defeat the purpose of the magnets. U.S. Pat. No. 2,655,740 to B. F. Goodrich shows a large scale display system. This system has a substantial bas panel that support hinged display with opposing surfaces to display messages. This invention is designed as an alternative to standard chalk black boards and would not be appropriate in a home environment. U.S. Pat. No. 98,458 to Bowman, George F. (1869) is a display device with a main hinge that interconnects the display with two covers. The device purpose is to provide a convenient, cheap frame for slat displays and a convenient mechanism for replacing said slate if the slat breaks. The invention steers away from the current invention presented in that its intended use is not for stationary applications.

Kurtz (U.S. Pat. No. 5,301,446) is a patent that include an addition item in the generic claim 1 claiming a (biasing means or imparting a biasing force to said planar cover member . . . ) that is not included (Omission of Element) in the current Application presented. Also, Kurtz teaches away from the current application in that the patent specification and generic claim 1 describes the invention for outdoor use and the additional need for wind that the Kurtz invention relies upon for the use of the invention. The wind and spring (biasing means) combination is vital to the use of the invention to function as described in the specifications. The current Application does not require these additional claims.

All of the message board designs are fixed in position once mounted. Some have a replaceable or compartment in addition to the message board but the emphasis on these additional features are additional compartment(s) for containing items or a surface that can be replaced for design reasons. All use a fixed position mounting to the surface that also restricts the message feature of the board. Since the message part is presented in parallel with the surface that the message board is mounted to, there is only one primary viewing angle to the message board. Also, The mounting of the prior art relies on multiple contact point covering the horizontal and vertical contact positions.

The following is a tabulation of some prior art that presently appears relevant:

### U. S. Patents

| Patent Number | Kind Code | Issue Date | Patentee |
|---|---|---|---|
| 7,374,142 | 248/206.5 | May 20, 2008 | Carnevali |
| 7,431,251 | 248/206.5 | Oct. 7, 2008 | Carnevali |
| 8,925,881 | 248/206.5 | Jan. 6, 2015 | Diatzikis |
| 6,425,560 | 248/206.5 | Jul. 30, 2002 | Dembowiak |
| 5,301,446 | 40/591 | Apr. 12, 1994 | Kurtz |
| 7,337,497 | 16/320 | Mar. 4, 2008 | Seidler; David |
| 8,861,224 | 361/810 | Oct. 14, 2014 | Griffin, Jason T |
| 7,934,330 | 40/711 | May 3, 2011 | Nicolaisen |
| 7,089,627 | 16/320 | Aug. 15, 2006 | Seidler; David |
| 7,040,899 | 434/430 | May 9, 2006 | Armstrong, Ronald G. |
| 5,948,498 | 428/81 | Sep. 7, 1999 | Bianco; Ronald M. |
| 5,987,825 | 52/36.1 | Nov. 23, 1999 | Rosen; Lawrence I. |
| 5,528,796 | 16/355 | Jun. 25, 1996 | Perry; John M. |
| 5,430,965 | 40/597 | Jul. 11, 1995 | Lai; Shih-Wang |
| 5,161,321 | 40/493 | Nov. 10, 1992 | Kuhnke, Horst F. |
| 5,131,849 | 434/281 | Oct. 4, 1991 | Perrero, John J. |
| 4,828,502 | 434/416 | May 9, 1998 | Leahy, David J. |
| 7,347,020 | 40/781 | Mar. 25, 2008 | Ray, et al. |
| 4,738,043 | 40/618 | Apr. 19, 1988 | Ernst, Paul F. |
| 4,869,452 | 248/441.1 | Sep. 26, 1989 | Bennett; Paul L. |
| 4,545,768 | 434/304 | Oct. 8, 1985 | Hinnen, John |
| 4,466,639 | 281/45 | Aug. 21, 1984 | Finnegan; Charles L. |
| 7,469,869 | 248/309.4 | Dec. 30, 2008 | Killion; Thomas |
| [symbol] | [symbol] | [symbol] | [symbol] |

[symbol]

indicates data missing or illegible when filed

### U. S. Patents Application Publications

| Patent Number | Kind Code | Issue Date | Patentee |
|---|---|---|---|
| 2007/0290588 | 312/401 | Dec. 20, 2007 | Oh; Seung-jin |
| 2006/0225331 | 40/600 | Oct. 12, 2006 | Evans, Rodney E. |

### Foreign Patents Documents

| | | | | App or |
|---|---|---|---|---|
| Foreign Doc. No | Cntry Code | Kind Code | Publ. Date | Patentee |
| [symbol] | [symbol] | [symbol] | [symbol] | [symbol] |

[symbol]

indicates data missing or illegible when filed

### Advantages

The hinge apparatus of the prior art relies on multiple contact point usually utilizing the horizontal and vertical dimensions of the display being supported. These designs needlessly require a large area in contact with a vertical mounting surface. The advantage of the current invention leaves clear the underlying surface by limiting the mounting area to the target vertical surface along only one edge of the message board. The depth of this pivot apparatus could be varied to easily close over existing items such as magnetic paper holders, pictures or even over other prior art flat mounted message boards. This Magnetic Pivot Apparatus For Verticle Mounting adds the advantage of allowing any type of clip board to be rotated out uniquely while providing a minimal vertical mounting surface edge. The pivot in this invention has a minimal width interface for the actual portion used to attach the message board to the vertical surface. This minimal contact reduces weight or the overall system, reduces the number of contact point with the wall and, more importantly, allows the pivot to be mounted directly to the surface without using a base panel which is typical in all prior art.

A particular application would be to use this apparatus to mount a message board to the side of a refrigerator. This would allow the message board to be position forward, 0 to 180 degrees, with the surface parallel to the front of the fridge to access messages. Then when not in use, the board could be rotated back, parallel with the mounting surface. The invention described is ideal for attaching to any thin metal strips such as those used in drywall corners which are typically constructed with a vertical ferrous metal strip along the length of the corner. This would allow easily moving the message display to many locations in a house without damage the walls or the need for any other mounting devices. A corner mounting on a vertical edge would also allow the display to swing from 0 to 270 degrees along the pivot

### DRAWINGS

FIG. 1—MAGNETIC PIVOT APPARATUS FOR VERTICLE MOUNTING—SINGLE AXIS

FIG. 1A—MAGNETIC PIVOT APPARATUS FOR VERTICLE MOUNTING—SINGLE AXIS

FIG. 1B—MAGNETIC PIVOT APPARATUS FOR VERTICLE MOUNTING—SINGLE AXIS

FIG. 2—MAGNETIC PIVOT APPARATUS FOR VERTICLE MOUNTING MULTI AXIS

FIG. 2A—MAGNETIC PIVOT APPARATUS FOR VERTICLE MOUNTING MULTI AXIS A

FIG. 3A—Home POSITIONS

FIG. 3B—Perpendicular POSITIONS

FIG. 3C—Extended POSITIONS

### DRAWINGS—LIST OF REFERENCE NUMERALS

10 Device to Mount

20 Pivot to Board Interface

30 Pivot-Board Side

40 Pivot-Elongated Mounting Surface Side

50 Magnetic Target Surface Interface

60 Pivot Means

70 Target Surface

### DETAILED DESCRIPTION

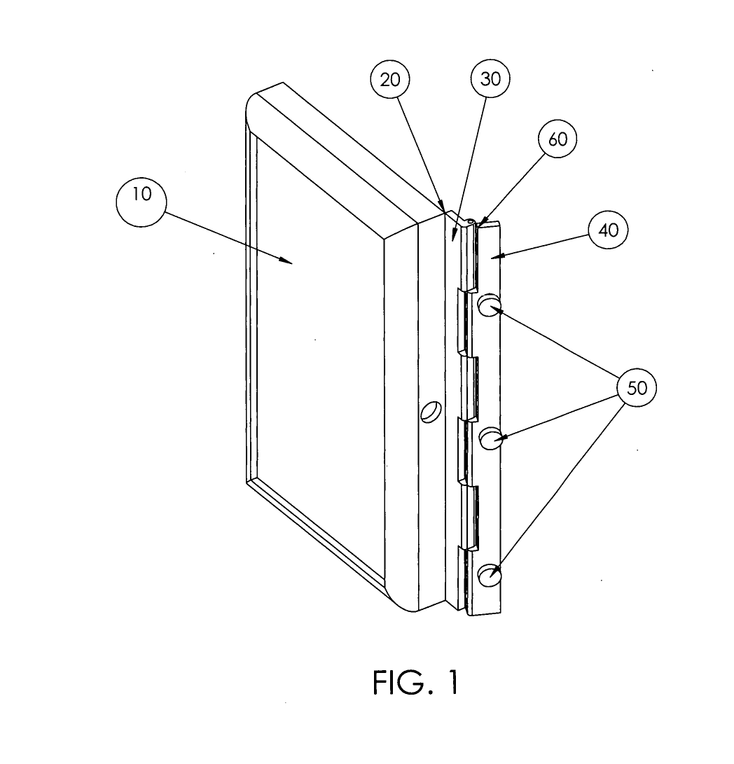

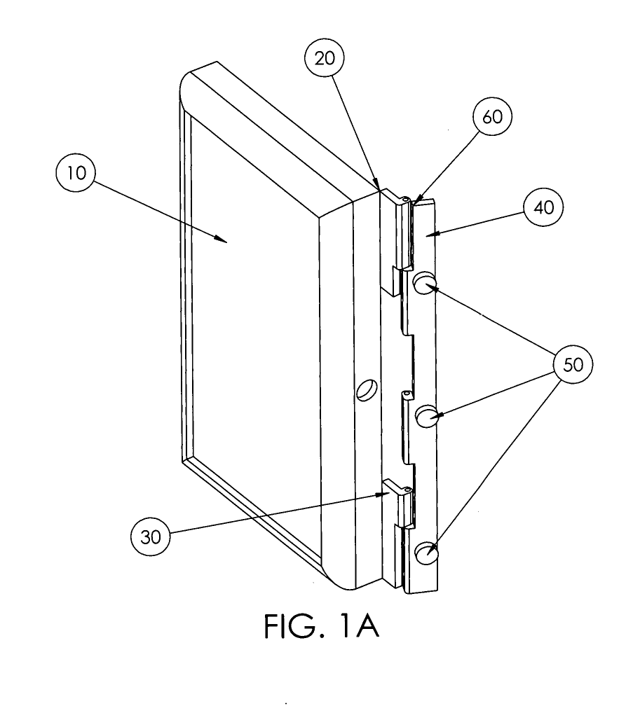

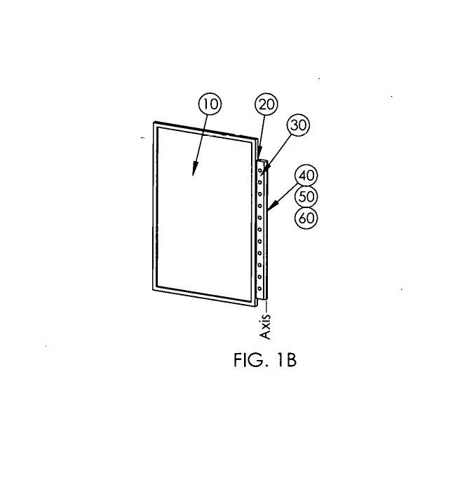

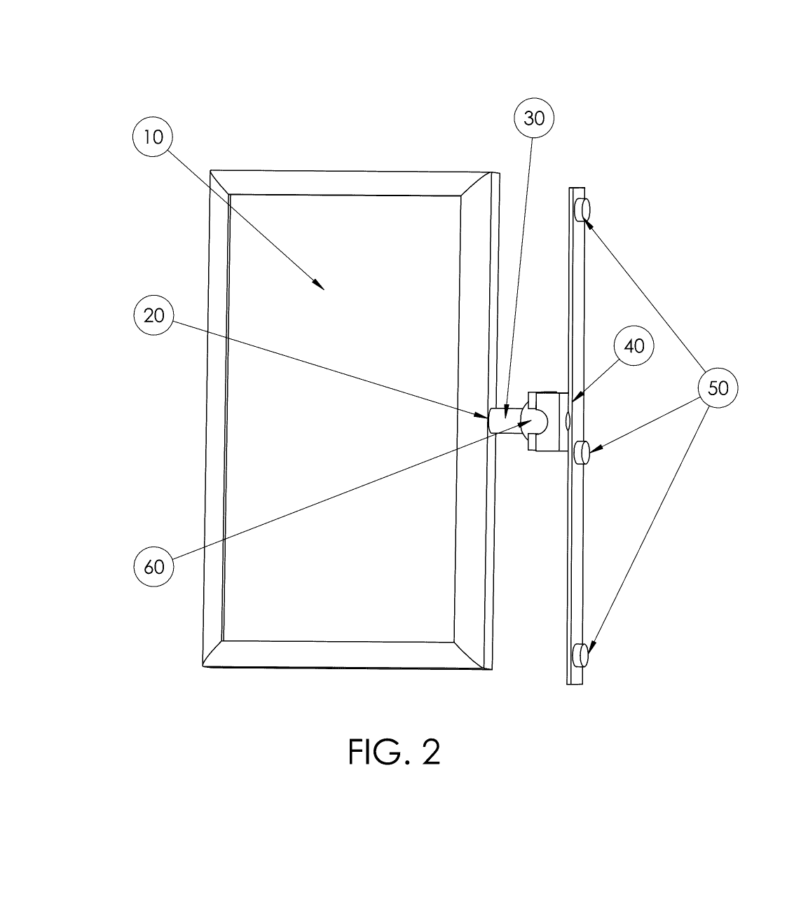

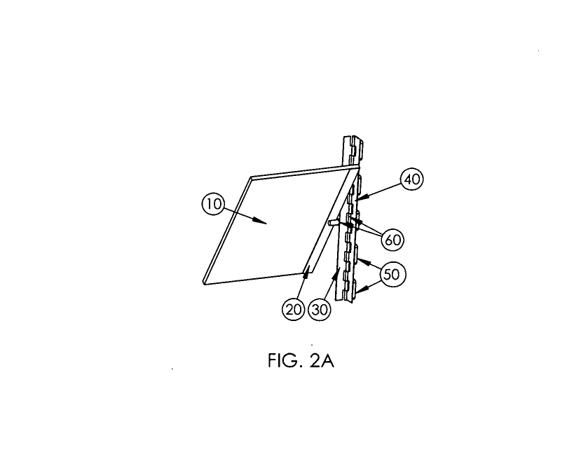

FIG. 2A shows the entire invention describes herein showing the major components of the invention and having a two axis Pivot Means 60. FIGS. 1, 1A, 1B are variation of the pivot apparatus that show one axis configurations. Note that in FIG. 1B the Pivot Elongated Mounting Surface side (40), Magnetic Target Surface Interface (50) and Pivot Means (60) are one and the same.

FIG. 2 shows a pivot axis around a single point using a ball-joint Pivot Means 60. This would allow the Device to Mount 10 to be rotated in the horizontal, vertical, and angular positions with reference to the ball joint pivot point.

A Device to Mount 10 is represented by a message board but can be any device to be mounted to a vertical edge. Variation would include marker eraser board, magnetic message boards, quark and material boards, LCD or other electronic displays, pictures, etc. FIG. 2A shows a Pivot Means 60 that consist of two axis of rotation with the first axis in the horizontal direction and the second axis is perpendicular to the first axis in the horizontal direction. The said first vertical Pivot Means 60 is located between the Pivot-Board Side 30 and the Pivot-Elongated Mounting Surface Side 40. Said first Pivot Means 60 shown uses a multi-cylindrical interlocking configuration that may have a solid shaft running through each interlocking piece. The said second horizontal Pivot Means 60 is located between the Pivot-Board Side 30 and the Pivot to Board Interface 20. Said second horizontal Pivot Means 60 consists of a single shaft mated with a cylinder to provide rotation of the Device to Mount 10 around the center of the shaft. The Device to Mount 10 can have a mounting means that is built into the device. This may include a receiving structure as part of the pivot, hinge, mounting holes or simple an edge that can be used to attach the hinge apparatus. The mounting means could also be added to an existing device by glue, clamp, screw, tape, weld, solder or other fastening method so that the device is securely mounted to the hinge apparatus describer herein.

An essential part of this invention is that said Pivot-Elongated Mounting Surface Side 40 be and elongated rigid surface oriented in the same direction of the said vertical axis. This invention is designed to a specific Target Surface 70 that is any outer corner of drywall construction that uses a metallic corner bead edging, and since most drywall metal corner beads are typically 1.5″ and 2.5″ in with, Pivot-Elongated Mounting Surface Side 40 should have a nominal width of 1.5″ to 2.5″ and an elongated length sufficient to mount the Magnetic Target Surface Interface 50 which consists of magnets. Though the invention described here-in is with reference to a vertical outer corner, this invention would also work for horizontal corners as well as non-corner metal studs used in most commercial construction. The length of the Pivot-Elongated Mounting Surface Side 40 can be varied to securely hold the entire weight of the invention plus the Device to Mount 10 based on the strength of the magnets used for the Magnetic Target Surface Interface 50. The length can also be varied in direct relation to the strength of the magnets used (the stronger the magnet, the shorter the overall length and vise versa). Though the Target Surface 70 is a metal edging, the invention could also be applied to and metallic surface dimension that provide a minimum surface are of the Pivot-Elongated Surface Side 40.

The Pivot to Board Interface 20 represents the contact of said Pivot-Board Side 30 with said Device to Mount 10. Said Pivot to Board Interface 20 can be built into said Device to Mount 10 and/or be an integral part of the Device to Mount 10.

Magnetic Target Surface Interface 50 shows a plurality of magnets that would cause said Pivot-Elongated Mounting Surface Side 40 to be secured with the proper shear and tear strength to the target surface to hold said Target Surface 70 along all pivotal positions desired along Pivot Means 60. Magnetic Target Surface Interface 50 could also be a single continuous magnet.

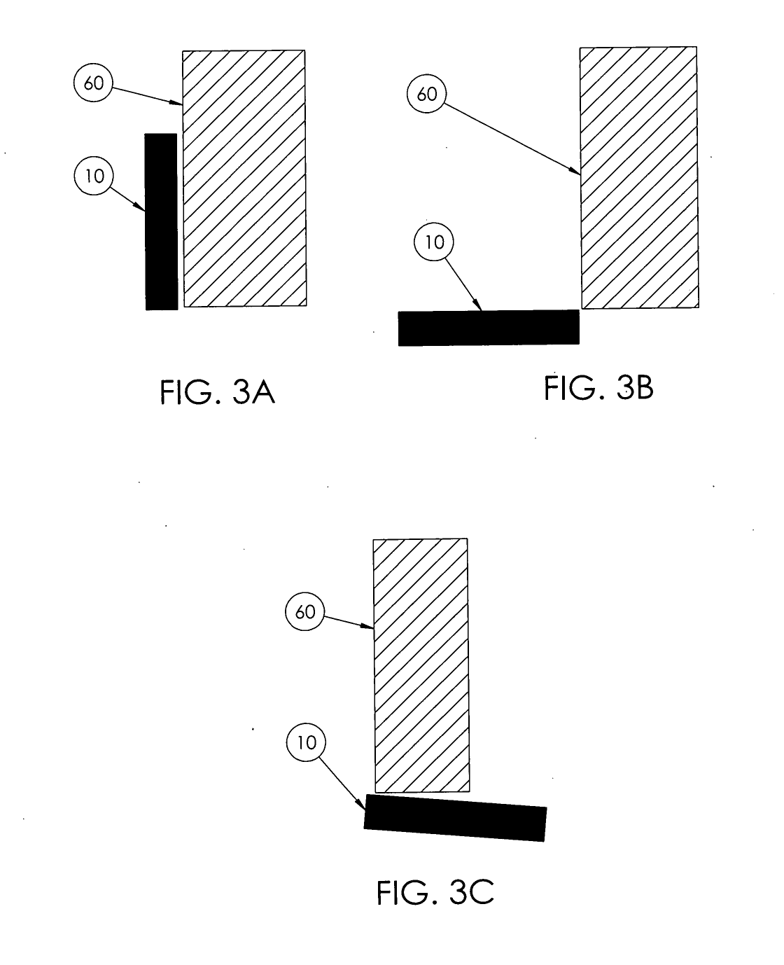

FIG. 3 shows the possible motion range for the said first Pivot Means 60.

### Operation

Magnetic Target Surface Interface 50 would be used to attach said Device to Mount 10 to a Target Surface that is metallic and specifically include outer drywall corners. The Elongated Mounting Surface Sided 40 will be parallel to the outer drywall corner, and therefore, perpendicular with the floor or ceiling. This would assure that the position of said Device to Mount 10 surface with reference to said target surface 70 to move from parallel with, to at least 90 degrees from, the target surface 70 (FIG. 3). The position of the board would remain stationary at any position (i.e. 10 °, 45°, 90°, 180°, 270°). In the case of a ball and socket pivot design, the Device to Mount 10 would also be allowed to tilt along the ball and socket joint for multi axis positioning.

### Conclusion, Ramifications, and Scope

The Magnetic Pivot Apparatus For Vertical Mounting invention described has the major advantage over existing by allowing any style Device to Mount 10 to be mounted to the corner of a wall with no additional hardware or damage to the wall. In addition, the invention disclosed can be used on more traditional targets such as a refrigerator. The invention disclosed has an advantage over prior art on the traditional refrigerator target by allowing the device to mount to be easily rotated perpendicular to the mounting surface to increase visibility or hidden by rotating flat, or parallel to the refrigerator surface. Also, since a predominant fridge door material is currently stainless steel, which is nonmagnetic, current, magnets and magnetic clip boards do not have sufficient ferrous material to create a good magnetic bond to (if any at all)

1. A single axis pivot means comprising;
a. a vertical elongated rigid mounting plate having a magnetic means surface and
b. a device interface side with a mounting means to
c. a device to mount.

2. The single axis pivot means of claim 1 wherein said magnetic means surface is a plurality of individual magnets.

3. The single axis pivot means of claim 1 wherein said magnetic means surface is a continuous magnet strip.

4. The single axis pivot means of claim 1 wherein said single axis pivot means is a continuous hinge in the form of a hole and peg combination along the single axis in parallel with said vertical elongated rigid mounting plate and where said device interface side is securely attached with said mounting means to said device to mount.

5. The single axis pivot means of claim 1 wherein said single axis pivot means is a plurality of hinge segments along the single axis and where said device interface side is securely attached with said mounting means to said device to mount.

6. The single axis pivot means of claim 1 wherein said vertical elongated rigid mounting plate is the magnetic means and whose axis pivot means is the rounded vertical edge directly in contact with said mounting surface.

7. The single axis pivot means of claim 1 wherein said elongated rigid mounting plate has a horizontal width less than 4″ in perpendicular with said single axis and a length sufficient to hold said device to mount dependant on the strength of said magnetic means.

8. The single axis pivot means of claim 1 where said device to mount is a message board.

9. The single axis pivot means of claim 1 wherein said device to mount is an electronic display.

10. The single axis pivot means of claim 1 wherein said mounting means is not an integral part of said device to mount and can allow selectively attached or detached.

11. The single axis pivot means of claim 1 wherein said mounting means is an integral part of said device to mount.

12. A multi axis pivot means comprising;
a. an vertical elongated rigid mounting plate having a magnetic means surface and
b. a device interface side with a mounting means to
c. a device to mount.

13. The multi axis pivot means of claim 12 wherein said multi axis pivot means is a single ball and socket hinge providing a plurality of axis around a single point allowing the said device to mount to rotate freely around this point through said mounting means.

14. The multi axis pivot means of claim 12 wherein said multi axis pivot means consist of two axis, one vertical axis that is parallel to said vertical elongated rigid mounting plate and a second horizontal axis that is perpendicular to said vertical axis allowing the said device to mount to rotate freely about both axis.

15. The multi axis pivot means of claim 12 wherein said vertical elongated rigid mounting plate has a horizontal width less than 4″.

16. The multi axis pivot means of claim 12 wherein said device to mount is a message board.

17. The multi axis pivot means of claim 12 wherein said device to mount is an electronic display.

18. The multi axis pivot means of claim 12 wherein said mounting means is not an integral part of said device to mount and can allow selectively attached or detached.

19. The multi axis pivot means of claim 12 wherein said mounting means is an integral part of said device to mount.

20. The multi axis pivot means of claim 12 wherein said elongated rigid mounting plate has a horizontal width less than 4″ in perpendicular with said vertical elongated rigid mounting plate and a length sufficient to hold said device to mount dependant on the strength of said magnetic means.
